(19) United States
(12) Patent Application Publication
(10) Pub. No.: US 2026/0189226 A1
(43) Pub. Date: Jul. 2, 2026

(54) HIGH-VOLTAGE DRIVERS USING LOW-VOLTAGE DEVICES WITH PROTECTION CIRCUITRY FOR HIGH ENDURANCE OPERATION

(71) Applicant: IM2 Solutions, Inc., Pleasanton, CA (US)

(72) Inventor: Tim LAO, Sacramento, CA (US)

(21) Appl. No.: 19/439,270

(22) Filed: Jan. 2, 2026

Related U.S. Application Data
(60) Provisional application No. 63/741,112, filed on Jan. 1, 2025.
(60) Provisional application No. 63/741,113, filed on Jan. 1, 2025.

(51) Int. Cl. H03K 17/081; H03K 19/003; H03K 19/20

(52) U.S. Cl. CPC H03K 17/08104; H03K 19/00315; H03K 19/00384; H03K 19/20

(57) ABSTRACT

Certain embodiments of present disclosure provide a high voltage (e.g., 3.3V) tolerant MOS gate unit implemented using low voltage (e.g., 1.8V) MOS transistors. The MOS gate unit comprises source, drain and gate terminals, and first, second and third transistors each configured to operate at a lower voltage (e.g., 1.8V). The first transistor has its source coupled to the source terminal and its drain coupled to the source of the second transistor. The third transistor has its source (or drain) coupled to the gate of the first transistor, its drain (or source) coupled to the gate terminal, and its gate coupled to the gate of the second transistor. The second transistor has its drain coupled to the drain terminal. The MOS gate unit functions the same as a MOS transistor configured to operate at a higher voltage (e.g., 3.3V) when a limiting voltage (e.g., 1.65V) significantly lower than the higher voltage is applied to the gate of the third transistor.

### CROSS REFERENCE TO RELATED APPLICATION

The present application claims the benefit of priority to U.S. Provisional Patent Application No. 63/741,112, filed Jan. 1, 2025, entitled “High-Voltage Drivers Using Low-Voltage Devices with Protection Circuitry for High Endurance Operation,” and U.S. Provisional Patent Application No. 63/741,113, filed Jan. 1, 2025, entitled “Voltage Regulator Detector for Wide Voltage Operation,” each of which is incorporated herein by reference in its entirety.

### FIELD

The present application is related to electronic circuits, and more particularly to high-voltage drivers using low-voltage devices with protection circuitry for high endurance operation.

### BACKGROUND

As process nodes become smaller and more advanced, the chip's external supply voltage also migrates from higher supply voltage to lower supply voltage, for example, from 3.3V to 1.8V power supply. Typically, if external power supply 3.3V is used, 3.3V devices are used in the design. If external power supply 1.8V is used, 1.8V devices are generally used in the design. Some foundries offer processes with both 3.3V devices and 1.8V devices to accommodate 3.3V and 1.8V single power supply applications. However, some foundries offer processes with only 1.8V devices. The 1.8V processes cannot accommodate 3.3V single external power supply applications. Using 3.3V power supply directly on 1.8V devices would cause reliability concerns and potential breakdown of the 1.8V devices. Therefore, the power supply voltage that can be used on the 1.8V devices is restricted. For example, to meet the specification and safe operating range of these 1.8V devices, the external power supply must not exceed 2V, and the voltage between the gate and the source (VGS or VSG) and the voltage between the source and drain (VDS or VSD) of the 1.8V devices must not exceed their respective limits of 2V.

### SUMMARY

Certain embodiments resolve this restriction and allow 1.8V devices to operate under 3.3V external power supply. Certain embodiments provide 3.3V MOS circuits using stacked 1.8V devices and protection circuitry to allow the circuits to operate at 3.3V and yet protect the 1.8V devices against potential breakdown.

In some implementation examples, a metal-oxide-semiconductor (MOS) gate unit comprises a source terminal, a drain terminal, a gate terminal, and first, second and third MOS transistors. Each of the first, second and third MOS transistors has a source, a drain, and a gate, and is configured to operate at a first operating voltage. The first MOS transistor has its source coupled to the source terminal of the MOS gate unit and its drain coupled to the source of the second MOS transistor. The third MOS transistor has one of its source and drain coupled to the gate of the first transistor, the other one of its source and drain coupled to the gate terminal, and its gate coupled to the gate of the second transistor. The drain of the second transistor is coupled to the drain terminal of the MOS gate unit. The MOS gate unit functions as a MOS transistor configured to operate at a second operating voltage significantly higher than the first operating voltage when a limiting voltage significantly lower than the second operating voltage is applied to the gate of the third transistor and the gate of the second transistor.

In some implementation examples, the second operating voltage is nearly twice the first operating voltage, and the limiting voltage is about half the second operating voltage.

In some implementation examples, the first operating voltage is about 1.8 V, the second operating voltage is about 3.3 V, and the limiting voltage is about 1.6 to about 1.85 V.

In some implementation examples, the MOS gate unit is turned on to form a conductive path between the source terminal and the drain terminal in response to a VSG or VGS voltage across the source terminal and the gate terminal being above a threshold voltage, and wherein the threshold voltage is about 60% of the second operating voltage.

In some implementation examples, when the MOS gate unit is turned on and the gate terminal receives a voltage signal varying between a first voltage level and a second voltage level higher than the first voltage level by about the second operating voltage, for each MOS transistor of the first, second and third MOS transistors, a VSG or VGS voltage between the source and the gate of the each MOS transistor does not exceed a VSG or VGS limit of the each MOS transistor, and a VSD or VDS voltage between the source and the drain of the each MOS transistor does not exceed a VSD or VDS limit of the each MOS transistor.

In some implementation examples, the VSG and VGS limit is significantly below the second operating voltage, and the VSD and VDS limit is significantly below the second operating voltage.

In some implementation examples, the second operating voltage is nearly twice the first operating voltage and the VSD and VDS limit is about 1.1 times the first operating voltage.

In some implementation examples, the MOS gate unit further comprises a weak diode coupled between the gate of the first MOS transistor and a power terminal of the MOS gate unit and configured to keep the VSG or VGS voltage between the source and the gate of the first MOS transistor within a VSG or VGS limit of the first MOS transistor when a voltage at the gate terminal of the MOS gate unit remains steady for a prolonged period of time, the weak diode including a plurality of serially connected diodes each configured to operate at the first operating voltage.

In some implementation examples, the MOS gate unit does not include any MOS transistor configured to operate at the second operating voltage.

In some implementation examples, an inverter comprises an input terminal, an output terminal, first and second voltage terminals, a p-type metal-oxide-semiconductor (PMOS) gate unit, and an n-type metal-oxide-semiconductor (NMOS) gate unit. The PMOS gate unit includes first, second and third PMOS transistors, each of the first, second and third PMOS transistors having a source, a drain and a gate, and configured to operate at a first operating voltage. The NMOS gate unit includes first, second and third NMOS transistors, each of the first, second and third NMOS transistors having a source, a drain and a gate, and configured to operate at the first operating voltage.

In some implementation examples, the first PMOS transistor has its source coupled to the first voltage terminal and its drain coupled to the source of the second PMOS transistor; the third PMOS transistor has its source coupled to the gate of the first PMOS transistor, its drain coupled to the input terminal, and its gate coupled to the gate of the second PMOS transistor; and the drain of the second PMOS transistor is coupled to the output terminal.

In some implementation examples, the first NMOS transistor has its source coupled to the second voltage terminal and its drain coupled to the source of the second NMOS transistor; the third NMOS transistor has its source coupled to the gate of the first NMOS transistor, its drain coupled to the input terminal, and its gate coupled to the gate of the second NMOS transistor; and the drain of the second NMOS transistor is coupled to the output terminal.

In some implementation examples, the inverter is operable at a second operating voltage significantly higher than the first operating voltage when a first limiting voltage significantly lower than the second operating voltage is applied to the gate of the third PMOS transistor and a second limiting voltage significantly lower than the second operating voltage is applied to the gate of the third NMOS transistor, the second operating voltage being applied across the first and second voltage terminals.

### BRIEF DESCRIPTION OF THE DRAWINGS

FIGS. 1A-1C are circuit diagrams of a 3.3V-tolerant PMOS gate implemented with 1.8V devices according to certain embodiments.

FIG. 2 is a circuit diagram of a 3.3V PMOS gate according to certain embodiments.

FIGS. 3A-3C are a circuit diagrams of a 3.3V-tolerant NMOS gate implemented with 1.8V devices according to certain embodiments.

FIG. 4 is a circuit diagram of a 3.3V NMOS gate according to certain embodiments.

FIG. 5 is a circuit diagram illustrating a 3.3V-tolerant inverter implemented with 1.8V devices, where examples of expected node voltage operating ranges are provided in parenthesis, where XVDD can vary between 2.7V to 3.6V, according to certain embodiments.

FIG. 6 is a circuit diagram illustrating a weak p-type diode (PDIO) according to certain embodiments.

FIG. 7 is a circuit diagram illustrating a weak n-type diode (NDIO) according to certain embodiments.

FIG. 8A is a circuit diagram of a 3.3V-tolerant inverter showing node voltages in normal operation when IN=0V (Low) according to certain embodiments.

FIG. 8B is a circuit diagram of a 3.3V-tolerant inverter showing node voltages in normal operation when IN=3.3V (High) according to certain embodiments.

FIG. 9 is a waveform diagram of the 3.3V-tolerant inverter shown in FIGS. 8A and 8B in normal operation according to certain embodiments.

FIG. 10A is a circuit diagram of a 3.3V-tolerant inverter showing node voltages in standby when IN=0V (Low) according to certain embodiments.

FIG. 10B is a waveform diagram of the 3.3V-tolerant inverter shown in FIG. 10A in standby when IN=0V (Low) according to certain embodiments.

FIG. 11B is a circuit diagram of a 3.3V-tolerant inverter showing node voltages in standby when IN=3.3V (High) according to certain embodiments.

FIG. 11B is a waveform diagram of the 3.3V-tolerant inverter shown in FIG. 10B in standby when IN=3.3V (High) according to certain embodiments.

### DESCRIPTION OF THE EMBODIMENTS

### Main Power and Signal Description

I. Power and ground:
   1. XVDD—External power supply (2.7V-3.6V).
   2. VSS—ground.
II. Signals:
   3. VGP—A global signal that is about half of the XVDD power supply, i.e., VGP ˜XVDD/2. For example, a default of VGP is 1.65V in the case XVDD=3.3V. VGP tracks and follows XVDD in the event XVDD changes. VGP is tunable or adjustable. VGP is connected to one of the stacked PMOS devices and provides breakdown protection by forcing a voltage drop across the VSD of stacked PMOS devices.
   4. VGN—A global signal that is a constant voltage of, e.g., 1.8V. VGN is also tunable or adjustable. VGN is connected to one of the stacked NMOS devices and provides breakdown protection by forcing a voltage drop across the VDS of the stacked NMOS devices.
   5. PG—The gate of one of the stacked PMOS devices. PG switches between (VGP+VTHp) to XVDD to sufficiently turn on the PMOS device and yet helps to protect it against dielectric breakdown.
   6. NG—The gate of one of the stacked NMOS devices. NG switches between 0 to (VGN−VTHn) to sufficiently turn on the NMOS device and yet helps to protect it against dielectric breakdown.

As discussed above, for a semiconductor chip to operate with external power supply at 3.3V, the devices (e.g., transistors) in the semiconductor chip need to be able to sustain 3.3V voltage drops across its nodes. However, some chip manufacturing facilities (or foundries) only offer processes for fabricating chips with 1.8V devices, which cannot accommodate 3.3V single external power supply application. Using 3.3V power supply directly on 1.8V devices would cause reliability concerns and potential breakdown of the 1.8V devices.

There are two breakdown mechanisms associated with using lower voltage (e.g., 1.8V) devices in chips that operate with a higher voltage (e.g., 3.3V) power supply. One is dielectric breakdown in which the limit for the voltage between the gate and the source nodes (source-gate voltage, VSG, or VGS) of the core devices is exceeded over a period of time. This is a time-dependent dielectric breakdown (TDDB) failure mechanism by which the gate oxide will eventually break down after sustaining a voltage over the VGS limit across the gate oxide for a certain period of time. The other is a hard breakdown (or source-drain VDS breakdown) mechanism. This occurs when the source-drain voltage (VDS or VSD) exceeds the VDS limit of the core devices.

In many cases, each of the VGS and VDS limit is about 110% of the operating voltage. Thus, to resolve the reliability concerns of using the lower voltage (e.g., 1.8V) devices for higher voltage (e.g., 3.3V) power supply, the VGS and VDS of, e.g., the 1.8V devices, must satisfy the following requirements: (1) VGS<=VGS limit (e.g., 2V); and (2) VDS<=VDS limit (e.g., 2V).

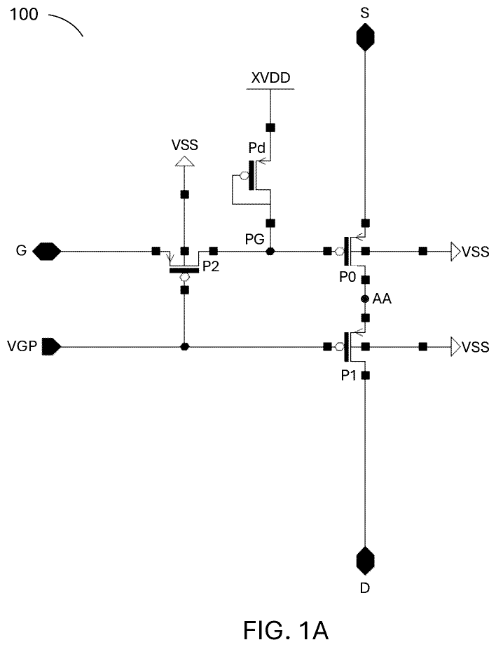

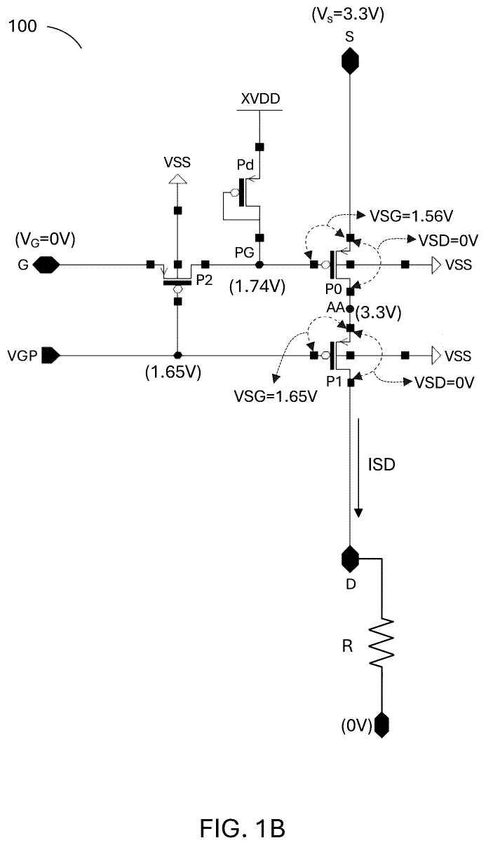

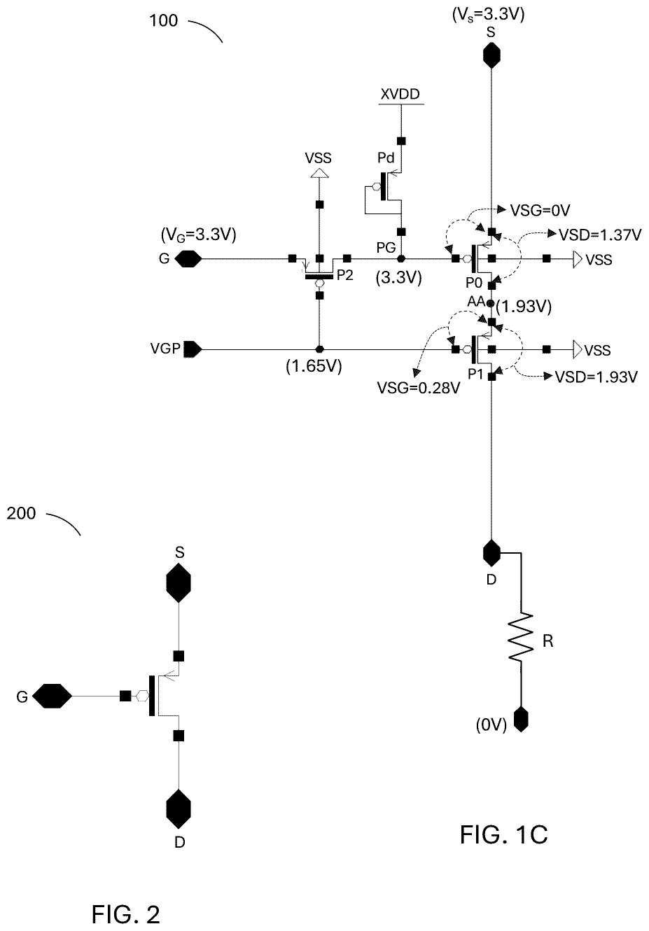

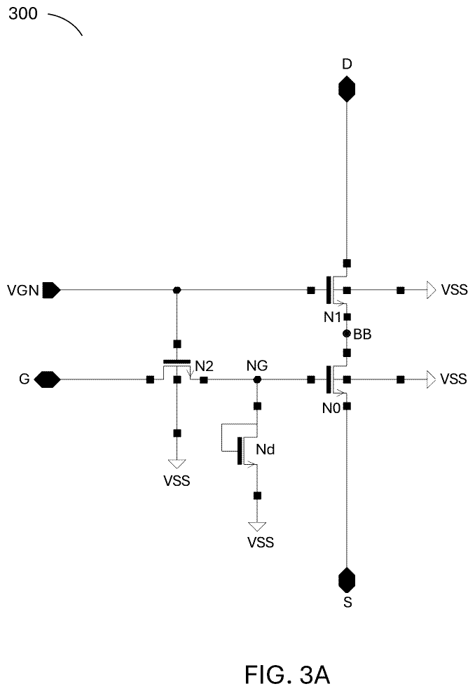

FIG. 1A shows a circuit implementation of a high voltage (e.g., 3.3V) tolerant p-type metal-oxide-semiconductor (PMOS) gate unit 100 using low voltage (e.g., 1.8V) devices according to certain embodiments. As described below, this PMOS gate unit 100 functions the same as and behaves similarly to a normal high voltage (e.g., 3.3V) PMOS device 200 shown in FIG. 2. As shown in FIG. 1A, like the normal high voltage (e.g., 3.3V) PMOS device 200 shown in FIG. 2, the high voltage (e.g., 3.3V) tolerant PMOS gate unit 100 has a gate terminal (G), a source terminal (S), and a drain terminal (D), each of which can be coupled to the high voltage (e.g., 3.3V) power supply XVDD or ground VSS.

As shown in FIG. 1A, the high voltage (e.g., 3.3V) tolerant PMOS gate unit 100 includes first and second low-voltage (e.g., 1.8V) PMOS devices P0 and P1. Each of PMOS devices P0 and P1 can be, for example, a p-type metal-oxide-semiconductor field-effect transistor (MOSFET), which has a gate, a source, and a drain. PMOS devices P0 and P1 are stacked, or connected to each other in series, between the source terminal S and the drain terminal D, so that the voltage drop between S and D does not fall entirely between the source and drain of either of the PMOS devices P0 and P1, preventing either of the PMOS devices P0 and P1 from experiencing hard breakdown (or source-drain VDS breakdown) and being blown out by the high voltage (e.g., 3.3V) power supply.

As shown in FIG. 1A, the first PMOS device P0 has its source coupled to the source terminal S of the MOS gate unit 100 and its drain coupled to the source of the second PMOS transistor P1. The second PMOS device P1 has its gate coupled to a VGP terminal, which is configured to receive a global signal of intermediate level between ground VSS and the high voltage (e.g., 3.3V). The MOS gate unit 100 further includes a third low-voltage PMOS device P2 that has its drain coupled to the gate of the first PMOS transistor P0, its source coupled to the gate terminal G, and its gate coupled to the gate of the second PMOS transistor P1.

VGP, which is about halfway (e.g., 1.65V) between XVDD (e.g., 3.3V) and VSS (e.g., 0V), is applied to the gate of P1 and limits the voltage at the gate of P0 via PMOS device P2. For example, the third PMOS device P2 is configured to keep a PG node between the gate of the first PMOS device P0 and the drain of the third PMOS device P2 at an intermediate voltage (e.g., 1.74V) when the voltage between the source terminal S and the gate terminal G of the PMOS gate unit 100 is at a high voltage (e.g., 3.3V), thus keeping the VSG voltage between the source and the gate of the first PMOS device P0 below the VSG limit of the first PMOS device P0. As a result, the voltage between any two terminals of P0 and P1 would not exceed 2V, preventing TDDB failure of each of P0 and P1. VGP (roughly one half of XVDD) can be a constant voltage or tracks the XVDD level by fluctuating with the XVDD.

In some embodiments, the PMOS gate unit 100 further includes a weak p-type diode (weak_pdio) Pd coupled between a power terminal for connecting to external power XVDD and the PG node, as discussed further below.

FIG. 1B illustrates the PMOS gate unit 100 showing voltages in the PMOS gate unit 100 when the voltage V_{S} at the source terminal is 3.3V, the voltage V_{G} at the gate terminal is 0V, the voltage VGP at the gate of the second PMOS device P1 is 1.65V, and the drain is coupled to ground (0V) via a resistor R having a resistance large enough that the source-drain resistance of each of P0 and P1 in the “on” state is negligible. As shown, the voltage at node PG is 1.74V, so the VSG voltage of P0 is 1.56V; this condition turns on P0, which is a 1.8V device, and connects node AA to the source terminal S. With VGP at 1.65V, the VSG voltage of P1 is at 1.65V and turns on P1, resulting in source-drain current ISD flowing between the source S and drain D terminals and through resistor R to the ground. In other words, the PMOS gate unit 100 is turned on or in an “on” state when the V_{S}−V_{G} is 3.3V.

In the “on” state, because P2 is off, disconnecting the PG node from the gate terminal G, the voltage at the PG node is at an intermediate voltage (e.g., 1.74V). With VGP at 1.65V and the voltage at the PG node at 1.74V, the VSG of P0 is at 1.56V, the VSG of P1 sis at 1.65V, and the VSG of P2 is at 0.09V, all below the VSG limit of 2V for the 1.8 devices. Also, the VSD of each of P1 and P2 is 0V, and the VSD of P2 is at 1.74V, all below the VSD limit of 2V for the 1.8 devices.

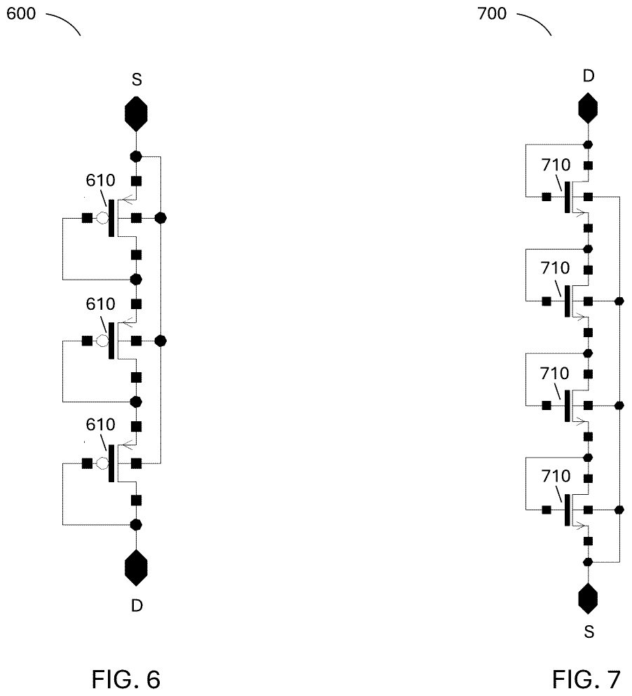

As discussed above, the PMOS gate unit 100 further includes a weak p-type diode (weak_pdio) Pd coupled between a power terminal for connecting to external power XVDD and the PG node. Without the weak_pdio Pd, if the source terminal S is coupled to XVDD at, e.g., 3.3V, and the gate terminal G remains steady at 0V for a prolonged period of time, the PG node would not be maintained at the intermediate level of, e.g., 1.74V. It would discharge and drop to zero over time due to leakage, resulting in the VSG voltage of P0 to rise above its VSG limit. The weak_pdio Pd is weak enough so that it does not interfere with the normal operations of the PMOS gate unit 100. When the PMOS gate unit 100 is maintained at steady state, the weak_pdio Pd would turn on to charge up the PG node whenever the voltage at the PG node drops below a certain value (e.g., 1.5V). As such, the weak_pdio Pd makes sure that the voltage at the PG node does not drop to zero when the PMOS gate unit is in steady state for a long time. In some embodiments, as shown in FIG. 6, the weak_pdio 600 may include multiple (e.g., 2-4) stacked p-type diodes (e.g., p-type diodes 610) to keep the PG node far from the power terminal.

FIG. 1C illustrates the PMOS gate unit 100 showing voltages in the PMOS gate unit 100 when the voltage V_{S} at the source terminal S is 3.3V, the voltage V_{G} at the gate terminal G is 3.3V, the voltage VGP at the gate of the second PMOS device P1 is 1.65V, and the drain D is coupled to ground (0V) via the resistor R. As shown, since the VSG voltage of P2 is 1.65V, P2 is turned on, connecting the PG node to the gate terminal G (e.g., the voltage at node PG is 3.3V). As a result, the VSG voltage of P0 is 0V, i.e., P0 is off, presenting a large source-drain resistance and reducing the voltage at the AA node between P0 and P1 to a value (e.g., 1.93V) insufficient to turn on P1 (since the gate of P1 is at 1.65V). Thus, P1 is off as well. In other words, the PMOS gate unit 100 is turned off or in an “off” state when the VS-VG voltage is 0V.

In the “off” state, because P0 and P1 are stacked between the source and drain terminals S and D, the nearly 3.3V voltage drop between the source and drain terminals is distributed between the two PMOS devices P0 and P1, resulting in the VSD voltage of P0 being at 1.37V and the VSD voltage of P1 being at 1.93V, safely under the VSD limit of 2V for the 1.8V PMOS devices P0 and P1.

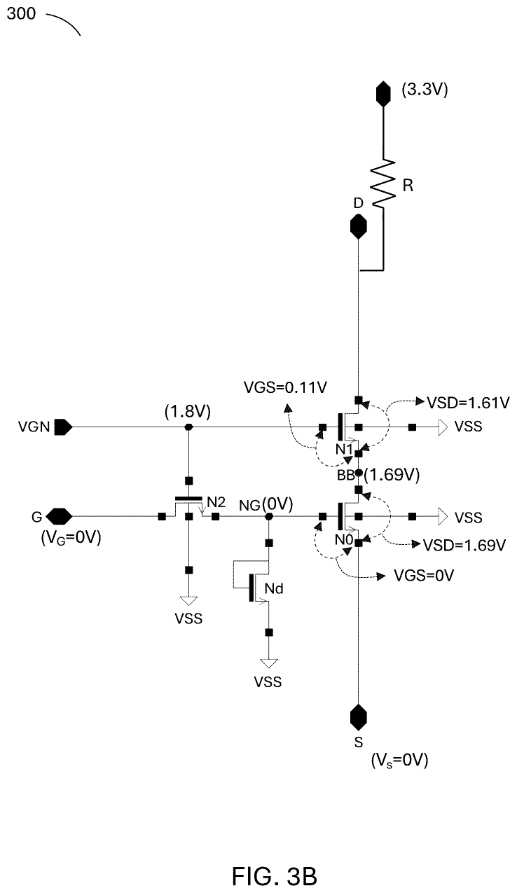

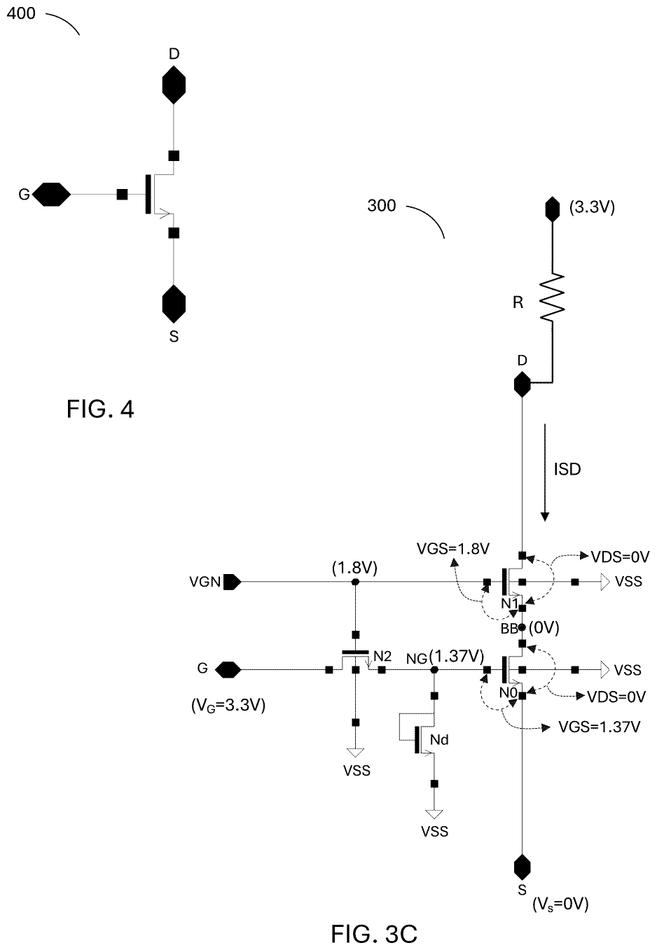

FIG. 3A shows a circuit implementation of a high voltage (e.g., 3.3V) tolerant n-type metal-oxide-semiconductor (NMOS) gate unit 300 using low voltage (e.g., 1.8V) devices according to certain embodiments. As described below, this NMOS gate unit 300 functions the same and behaves similarly as a normal high voltage (e.g., 3.3V) NMOS device 400 shown in FIG. 4. As shown in FIG. 3A, like the normal high voltage (e.g., 3.3V) NMOS device 400 shown in FIG. 4, the high voltage (e.g., 3.3V) tolerant NMOS gate unit 300 has a gate terminal (G), a source terminal (S), and a drain terminal (D), each of which can be coupled to the high voltage (e.g., 3.3V) power supply XVDD or ground VSS.

As shown in FIG. 3A, the high voltage (e.g., 3.3V) tolerant NMOS gate unit 300 includes first and second low voltage (e.g., 1.8V) NMOS devices N0 and N1. Each of NMOS devices N0 and N1 can be, for example, a n-type metal-oxide-semiconductor field-effect transistor (MOSFET), which has a gate, a source and a drain. NMOS devices N0 and N1 are stacked, or connected to each other in series, between the source terminal S and the drain terminal D, so that the voltage drop between S and D does not fall entirely between the source and drain of either of the NMOS devices N0 and N1, preventing either of the NMOS devices N0 and N1 from experiencing hard breakdown (or source-drain VDS breakdown) and being blown out by the high voltage (e.g., 3.3V) power supply.

As shown in FIG. 3A, the first NMOS device N0 has its source coupled to the source terminal S of the NMOS gate unit 300 and its drain coupled to the source of the second NMOS transistor N1. The second NMOS device N1 has its gate coupled to a VGN terminal, which is configured to receive a global signal of intermediate level between ground and the high voltage (e.g., 3.3V). The NMOS gate unit 300 further includes a third NMOS device N2 that has its source coupled to the gate of the first NMOS transistor N0, its drain coupled to the gate terminal G, and its gate coupled to the gate of the second NMOS transistor N1.

VGN (e.g., 1.8V), which is roughly at or a little over midway between XVDD (e.g., 3.3V and VSS (e.g., 0V), is applied to the gate of N1 and limits the voltage at the gate of N0 via NMOS device N2. For example, the third NMOS device N2 is configured to keep a NG node between the gate of the first NMOS device N0 and the source of the third NMOS device N2 at an intermediate voltage (e.g., 1.37V) when the voltage between the gate terminal G and the source terminal S of the NMOS gate unit 300 is at a high voltage (e.g., 3.3V), thus keeping the VSG voltage between the source and the gate of the first NMOS device N0 below the VSG limit of the first NMOS device N0. As a result, the voltage between any two terminals of N0 and N1 would not exceed 2V, preventing TDDB failure of each of N0 and N1. VGN (roughly half or a little over half of XVDD) can be a constant voltage or tracks the XVDD level by fluctuating with the XVDD.

In some embodiments, the NMOS gate unit further includes a weak n-type diode (weak_ndio) Nd coupled between a ground terminal for connecting to ground and the NG node, as discussed further below.

FIG. 3B illustrates the NMOS gate unit 300 showing voltages in the NMOS gate unit 300 when the voltage V_{S} at the source terminal is grounded at 0V, the voltage V_{G} at the gate terminal is 0V, the voltage VGN at the gate of the second NMOS device N1 is 1.8V, and the drain D is coupled to power supply at 3.3V via a resistor R having a resistance large enough that the source-drain resistance of each of N0 and N1 in the “on” state is negligible. As shown, with VGN at 1.8V and V_{G} at 0V, N2 is turned on, connecting the gate of N0 to the gate terminal G, so VGS voltage of N0 is 0V, i.e., N0 is off, presenting a large source-drain resistance and reducing the voltage at the BB node between N0 and N1 to a value (e.g., 1.69V) insufficient to turn on N1 since the gate of N1 is at 1.8V). Thus, N1 is off as well. In other words, the NMOS gate unit 300 is turned off or in an “off” state when V_{G}−V_{S} is 0V.

In the “off” state, because N0 and N1 are stacked between the source and drain terminals S and D, the nearly 3.3V voltage drop between the source and drain terminals S and D is distributed between the two NMOS devices N0 and N1, resulting in the VSD voltage of N0 being at 1.69V and the VSD voltage of N1 being at 1.61V, well under the VSD limit of 2V for the 1.8V NMOS devices N0 and N1.

FIG. 3C illustrates the NMOS gate unit 300 showing voltages in the NMOS gate unit 300 when the voltage VS at the source terminal is 0V, the voltage VG at the gate terminal is 3.3V, the voltage VGN at the gate of the second NMOS device N1 is 1.8V, and the drain D is coupled to the power supply voltage of 3.3V via the resistor R. As shown, the voltage at node NG is 1.37V, so the VGS voltage of N0 is 1.37V; this turns on N0, which is a 1.8V device, and connects node BB to the source terminal S. With VGN at 1.8V, the VGS of N1 is at 1.8V; thus N1 is turned on, resulting in source-drain current ISD flowing between the source and drain terminals, S and D, and through resistor R to the ground. In other words, the NMOS gate unit 300 is turned on or in an “on” state when V_{G}−V_{S} is 3.3V.

In the “on” state, because N2 is off, disconnecting the NG node from the gate terminal G, the voltage at the NG node is at an intermediate voltage (e.g., 1.37V). With VGN at 1.8V and the voltage at the NG node at 1.37V, the VGS of N0 is at 1.37V, the VGS of N1 is at 1.8V, and the VGS of N2 is at 0.43V, all below the VGS limit of 2V for the 1.8 devices. Also, the VDS of each of N1 and N2 is 0V, and the VDS of N2 is at 1.93V, all below the VDS limit of 2V for the 1.8 devices.

As discussed above, the NMOS gate unit further includes a weak n-type diode (weak_ndio) Nd coupled between the NG node and a ground terminal for connecting to ground. Without the weak_ndio Nd, if the source terminal S is coupled to ground at, e.g., 0V, and the gate terminal G remains steady at 3.3V, over time, the NG node would not be maintained at the intermediate level of, e.g., 1.37V. It would charge up and rise to a higher voltage over time due to leakage. The weak_ndio Nd is weak enough so that it does not interfere with the normal operations of the NMOS gate unit 300. When the NMOS gate unit 300 is maintained at steady state, the weak_ndio Nd would turn on to discharge the NG node whenever the voltage at the NG node rises above a certain value (e.g., 1.5V). Thus the weak_ndio Nd ensures that voltage at the NG node does not rise significantly when the NMOS gate unit is in steady state for a long time. In some embodiments, as shown in FIG. 7, the weak_ndio 700 may include multiple (e.g., 2-4) stacked n-type diodes 710 to keep the NG node far from the power terminal.

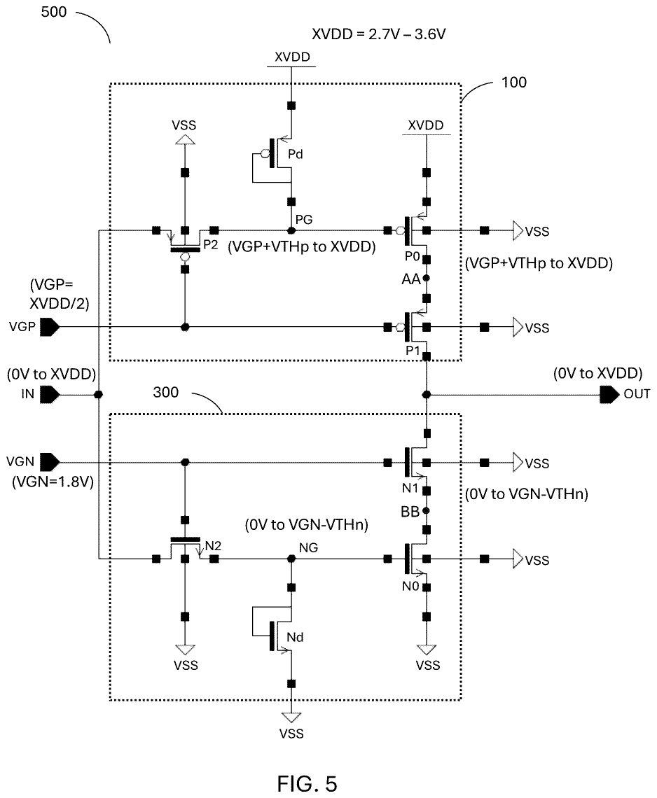

FIG. 5 illustrates a 3.3V tolerant inverter 500 including the PMOS gate unit 100 and the NMOS gate unit 300 according to certain embodiments. The inverter 500 is a basic and fundamental gate or block of most circuit designs. This 3.3V tolerant inverter is implemented with 1.8V devices. The inverter 500, including the PMOS stacked devices P0 and P1 and the NMOS stacked devices N0 and N1 with their respective protection circuitry shown in FIGS. 1A and 3A, can be used to create logic gates such as NAND, NOR, or other high voltage related blocks or circuitry.

Referring to FIG. 5, the power supply XVDD can vary between 2.7V to 3.6V. VGP is a global signal that is about half of the XVDD power supply (VGP=XVDD/2). VGP can track and follow XVDD whenever XVDD changes. For example, VGP=1.65V when XVDD=3.3V. VGN is a global signal that is a constant voltage of 1.8V. VGP and VGN can be generated from external power supply XVDD in analog circuit block. Input “IN” can switch between 0 and XVDD. Output “OUT” can also switch between 0 and XVDD in response to the input “IN”.

In some embodiments, with VGP established, when IN=0V, PG drops to VGP+VTHp, where VTHp is the threshold voltage of P2. When IN=XVDD, PG reaches XVDD.

In some embodiments, with VGN established, when IN=0V, NG reaches 0V. When IN=XVDD, NG drops to VGN-VTHn, where VTHn is the threshold voltage of N2.

In some embodiments, PG does not fall fully down to 0V and NG does not rise fully up to XVDD. Otherwise, they would violate the VGS limit of the 1.8V devices P0 and N0. Instead, P2 limits the fall of PG to only VGP+VTHp and N2 limits the rise of NG to only VGN-VTHn. Therefore, PG varies between (VGP+VTHp) to XVDD, and NG varies between 0V to (VGN-VTHn).

VGP, VGN, and the limited variation of PG and NG would limit the VGS of these stacked devices to below the VGS limit requirement, thus protecting them against dielectric breakdown. The VGP at the gate of P1 and VGN at the gate of N1 would force a voltage drop from XVDD or ground at node AA or BB. This helps to prevent source-drain breakdown.

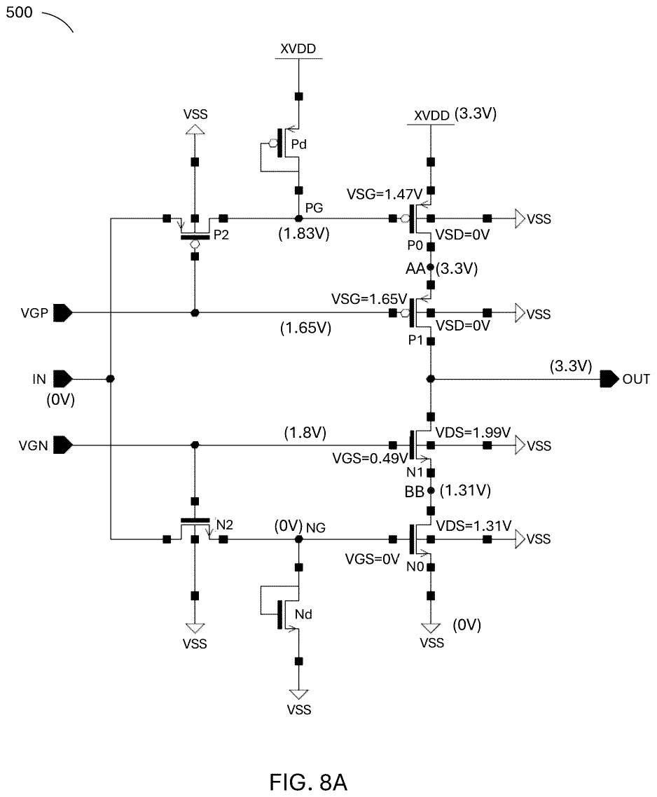

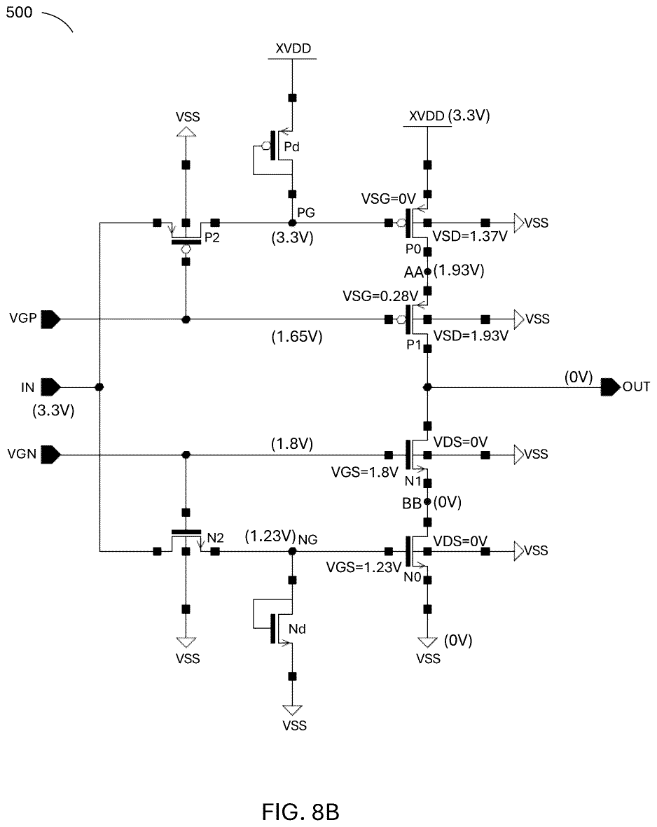

FIG. 8A shows an example of the inverter 500 operating at XVDD=3.3V and when IN=0V. As shown, when IN=0V, PG=1.83V; VSG of P0=1.47V and VSG of P1=1.65V, both less than the VSG limit of 2V; and VSD of P0=0V and VSD of P1=0V, both less than the VSD limit of 2V. Thus, VSG and VSD of the PMOS stacked devices meet the VSG and VSD limit requirement.

Also, when IN=0V, NG=0V; VGS of N0=0V and VGS of N1=0.49V, both less than the VGS limit of 2V; and VDS of N0=1.31V and VDS of N1=1.99V, both less than the VDS limit of 2V. Thus, VGS and VDS of the NMOS stacked devices meet the VGS and VDS limit requirement.

FIG. 8B shows an example of the inverter 500 operating at XVDD=3.3V and when IN=3.3V. As shown, when IN=3.3V, PG=3.3V; VSG of P0=0V and VSG of P1=0.28V, both less than the VSG limit of 2V; and VSD of P0=1.37V and VSD of P1=1.93V, both less than the VSD limit of 2V. Thus, VSG and VSD of the PMOS stacked devices meet the VSG and VSD limit requirement.

Also, when IN=3.3V, NG=1.23V; VGS of N0=1.23V and VGS of N1=1.8V, both less than the VGS limit of 2V; and VDS of N0=0V and VDS of N1=0V, both less than the VDS limit of 2V. Thus, VGS and VDS of the NMOS stacked devices meet the VGS and VDS limit requirement.

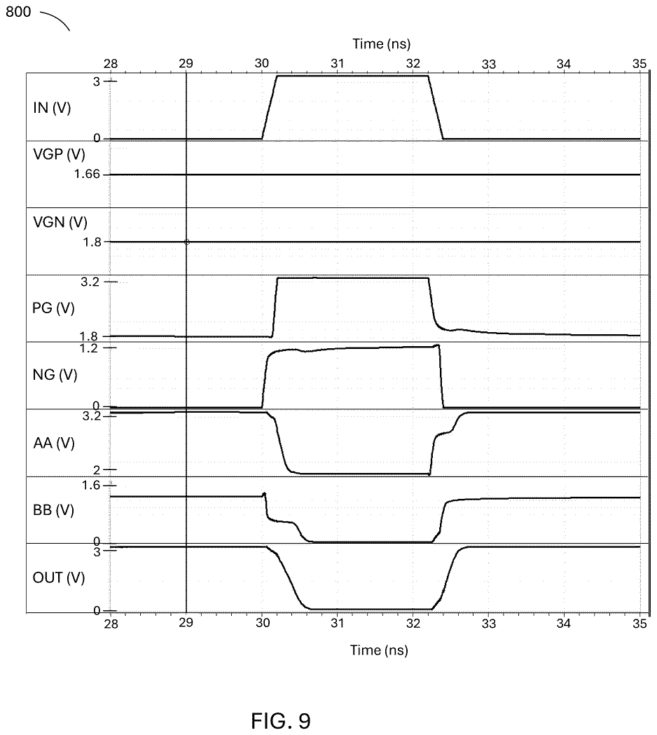

FIG. 9 illustrates an example of waveforms at various nodes of the inverter 500 when the voltage at IN varies between 0V and 3.3V according to some embodiment. As shown, the voltage at OUT varies in response between 3.3V and 0V, inversely to the voltage at IN.

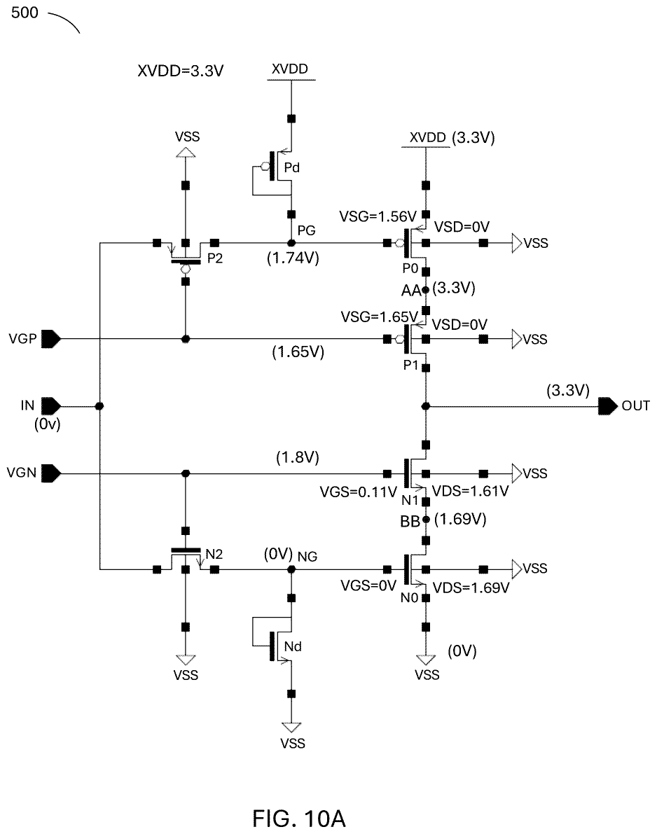

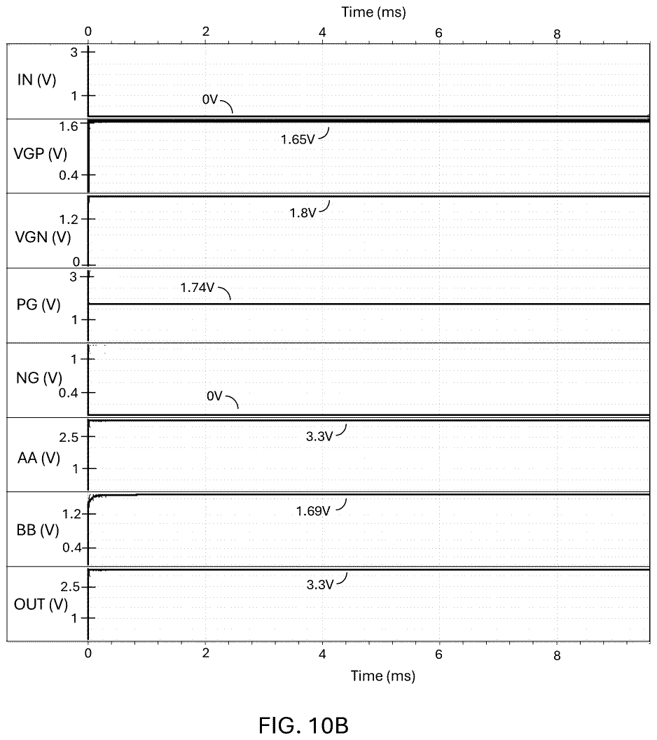

FIG. 10A shows an example of the inverter 500 operating at XVDD=3.3V and IN=0V, but in standby condition over an extended period of time. FIG. 10B shows the corresponding waveform diagram of the operation. As discussed above, when IN switches from 3.3V to 0V, node PG, having a small node capacitance, would eventually leak to ground (without the weak PMOS diode). PG at 0V would cause VSG of P0 to surpass the corresponding limit. A weak PMOS diode IDP (weak_pdio) Pd is placed at node PG to prevent this leakage and to maintain PG at an intermediate level to meet the VSG limit requirement. In this example, PG is maintained at 1.74V and VSG=1.56V (P0) would meet the VSG limit requirement.

This weak PMOS diode Pd is weak enough so that it does not interfere with the normal operation of when IN is driving PG. However, the weak PMOS diode Pd needs enough current to prevent PG node from slowly leaking to ground. The circuit implementation of the weak PMOS diode (weak_pdio) Pd is shown in FIG. 6.

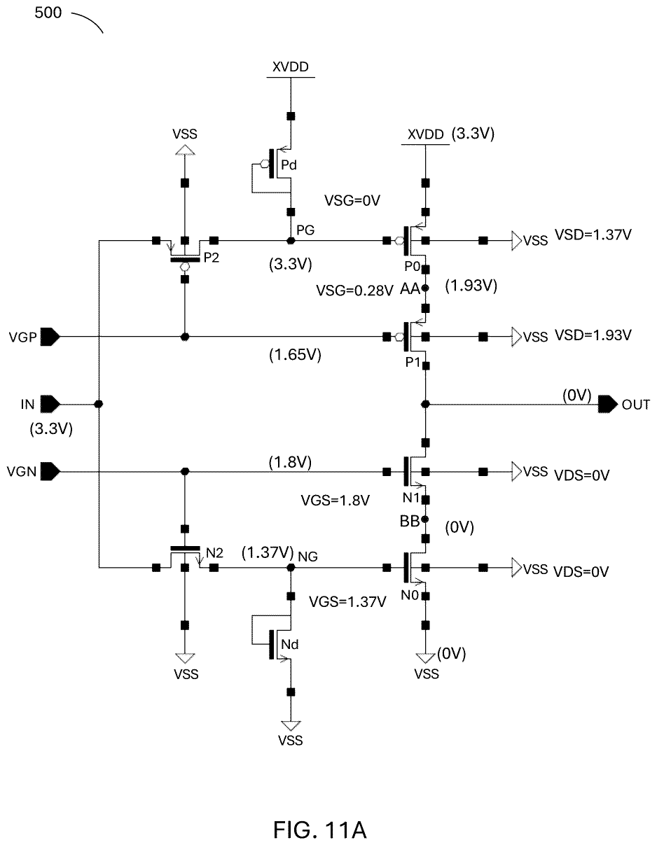

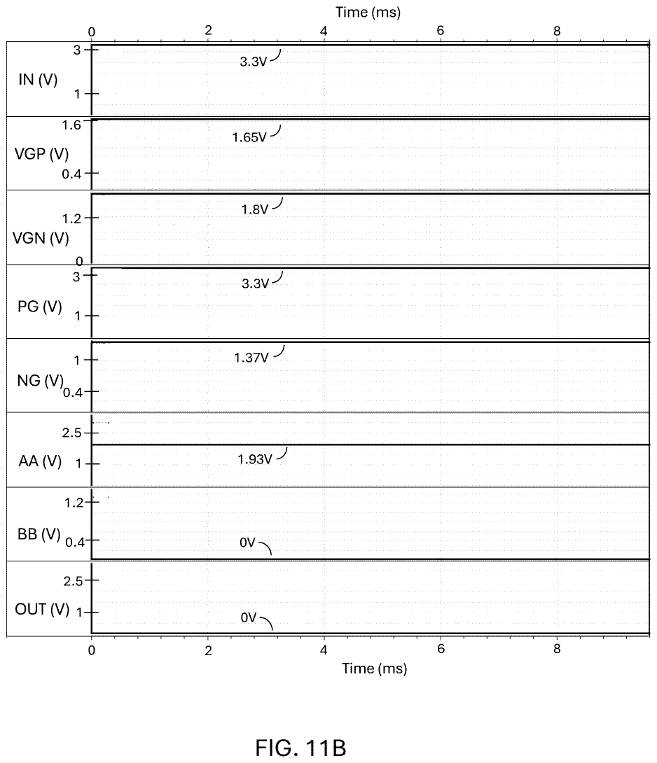

FIG. 11A shows an example of the inverter operating at XVDD=3.3V and IN=3.3V, but in standby condition over an extended period of time. FIG. 11B shows the corresponding waveform diagram of the operation. As discussed above, when IN switches from 0V to 3.3V, node NG, having a small node capacitance, would eventually be driven to close to 3.3V-VTHn (which is approximately 3.0V) (without the weak PMOS diode). NG at 3V would violate the VGS limit of N0.

A weak NMOS diode IDN (weak_ndio) Nd is placed at node NG to prevent NG from being driven too high and to maintain NG at an intermediate level to meet the VGS limit requirement. In this example, NG is maintained at 1.37V, and VGS=1.37V (for N0) would meet the VGS limit requirement.

This weak NMOS diode Nd is weak enough so that it does not interfere with the normal operation of when IN is driving NG. However, the weak NMOS diode Nd needs enough current to prevent NG node from slowly driven to 3V. The circuit implementation of the weak NMOS diode (weak_ndio) Nd is shown in FIG. 7.

What is claimed is:

1. A metal-oxide-semiconductor (MOS) gate unit, comprising:
a source terminal, a drain terminal, and a gate terminal; and
first, second and third MOS transistors, each of the first, second and third MOS transistors having a source, a drain and a gate, and configured to operate at a first operating voltage; wherein:
the first MOS transistor has its source coupled to the source terminal of the MOS gate unit and its drain coupled to the source of the second MOS transistor;
the third MOS transistor has one of its source and drain coupled to the gate of the first transistor, the other one of its source and drain coupled to the gate terminal, and its gate coupled to the gate of the second transistor;
the drain of the second transistor is coupled to the drain terminal of the MOS gate unit; and
the MOS gate unit is operable as a MOS transistor at a second operating voltage significantly higher than the first operating voltage when a limiting voltage significantly lower than the second operating voltage is applied to the gate of the third transistor.

2. The MOS gate unit of claim 1, wherein the first operating voltage is about 50-60% of the second operating voltage and wherein the limiting voltage is about half the second operating voltage.

3. The MOS gate unit of claim 2, wherein the first operating voltage is about 1.8 V, the second operating voltage is about 3.3 V, and the limiting voltage is about 1.6 to about 1.85 V.

4. The MOS gate unit of claim 1, wherein the MOS gate unit is turned on to form a conductive path between the source terminal and the drain terminal in response to a VSG voltage across the source terminal and the gate terminal being above a threshold voltage, and wherein the threshold voltage is about 60% of the second operating voltage.

5. The MOS gate unit of claim 4, wherein, when the MOS gate unit is turned on and the gate terminal receives a voltage signal varying between a first voltage level and a second voltage level higher than the first voltage level by about the second operating voltage, a VSG voltage between the source and the gate of each MOS transistor of the first, second and third MOS transistors does not exceed a VSG limit of the each MOS transistor, and a VSD voltage between the source and the drain of the each MOS transistor does not exceed a VSD limit of the each MOS transistor.

6. The MOS gate unit of claim 5, wherein the VSG limit is significantly below the second operating voltage, and the VSD limit is significantly below the second operating voltage.

7. The MOS gate unit of claim 6, wherein the VSD limit is about 1.1 times the first operating voltage and about 60% of the second operating voltage.

8. The MOS gate unit of claim 1, further comprising a weak diode coupled between the gate of the first MOS transistor and a power terminal of the MOS gate unit and configured to keep the VSG voltage between the source and the gate of the first MOS transistor within a VSG limit of the first MOS transistor when a voltage at the gate terminal of the MOS gate unit remains steady for a prolonged period of time, the weak diode including a plurality of serially connected diodes each configured to operate at the first operating voltage.

9. The MOS gate unit of claim 1, wherein the MOS gate unit does not include any MOS transistor configured to operate at the second operating voltage.

10. An inverter, comprising:
an input terminal, an output terminal, and first and second voltage terminals;
a p-type metal-oxide-semiconductor (PMOS) MOS gate unit, the PMOS MOS gate unit including first, second and third PMOS transistors, each of the first, second and third PMOS transistors having a source, a drain and a gate, and configured to operate at a first operating voltage; and
an n-type metal-oxide-semiconductor (NMOS) MOS gate unit, the NMOS MOS gate unit including first, second and third NMOS transistors, each of the first, second and third NMOS transistors having a source, a drain and a gate, and configured to operate at the first operating voltage;
wherein:
the first PMOS transistor has its source coupled to the first voltage terminal and its drain coupled to the source of the second PMOS transistor;
the third PMOS transistor has its source coupled to the gate of the first PMOS transistor, its drain coupled to the input terminal, and its gate coupled to the gate of the second PMOS transistor;
the drain of the second PMOS transistor is coupled to the output terminal;
the first NMOS transistor has its source coupled to the second voltage terminal and its drain coupled to the source of the second NMOS transistor;
the third NMOS transistor has its source coupled to the gate of the first NMOS transistor, its drain coupled to the input terminal, and its gate coupled to the gate of the second NMOS transistor;
the drain of the second NPMOS transistor is coupled to the output terminal; and
the inverter is operable at a second operating voltage significantly higher than the first operating voltage when a first limiting voltage significantly lower than the second operating voltage is applied to the gate of the third PMOS transistor and a second limiting voltage significantly lower than the second operating voltage is applied to the gate of the third NMOS transistor, the second operating voltage being applied across the first and second voltage terminals.

11. The inverter of claim 1, wherein the first operating voltage is about 50-60% of the second operating voltage and wherein the limiting voltage is about half the second operating voltage.

12. The inverter of claim 11, wherein the first operating voltage is about 1.8 V, the second operating voltage is about 3.3 V, and the limiting voltage is about 1.6 to about 1.85 V.

13. A metal-oxide-semiconductor (MOS) gate unit, comprising:
a source terminal, a drain terminal, and a gate terminal; and
first, second and third MOS transistors, each of the first, second and third MOS transistors having first and second current-carrying terminals and a control terminal, and configured to operate in a first operating voltage; wherein:
the first MOS transistor has its first current-carrying terminal coupled to the source terminal of the MOS gate unit and its second current-carrying terminal coupled to the first current-carrying terminal of the second MOS transistor;
the third MOS transistor has its first current-carrying terminal coupled to the control terminal of the first transistor, its second current-carrying terminal coupled to the gate terminal, and its control terminal coupled to the control terminal of the second transistor;
the second current-carrying terminal of the second transistor is coupled to the drain terminal of the MOS gate unit; and
the MOS gate unit is operable as a MOS transistor in a second operating voltage significantly higher than the first operating voltage when a limiting voltage significantly lower higher than the second operating voltage is applied to the control terminal of the third transistor.

14. The MOS gate unit of claim 13, wherein the first operating voltage is about 50-60% of the second operating voltage and wherein the limiting voltage is about half the second operating voltage.

15. The MOS gate unit of claim 14, wherein the first operating voltage is about 1.8 V, the second operating voltage is about 3.3 V, and the limiting voltage is about 1.6 to about 1.85 V.

16. The MOS gate unit of claim 13, wherein the MOS gate unit is turned on to form a conductive path between the source terminal and the drain terminal in response to a VSG voltage across the source terminal and the gate terminal being above a threshold voltage, and wherein the threshold voltage is about 60% of the second operating voltage.

17. The MOS gate unit of claim 16, wherein, when the MOS gate unit is turned on and the gate terminal receives a voltage signal varying between a first voltage level and a second voltage level higher than the first voltage level by about the second operating voltage, a VSG voltage between any two terminals of each MOS transistor of the first, second and third MOS transistors does not exceed a corresponding limit of the each MOS transistor, the corresponding limit being about 50-60% the second operating voltage.

18. The MOS gate unit of claim 13, further comprising a weak diode coupled between the control of the first MOS transistor and a power terminal of the MOS gate unit, and configured to keep a voltage between the control terminal and the first or second currently-carrying terminal of the first MOS transistor within a preset limit of the first MOS transistor when a voltage at the gate terminal of the MOS gate unit remains steady for a prolonged period of time, the weak diode including a plurality of serially connected diodes each configured to operate at the first operating voltage.

19. The MOS gate unit of claim 13, wherein the MOS gate unit does not include any MOS transistor configured to operate at the second operating voltage.
